(19) United States
(12) Patent Application Publication
(10) Pub. No.: US 2019/0206347 A1
(43) Pub. Date: Jul. 4, 2019

(54) SHIFT REGISTER CIRCUIT, METHOD FOR GENERATING WAVEFORM THEREOF, AND DISPLAY PANEL APPLYING SAME

(71) Applicants: HKC Corporation Limited, Shenzhen City, Guangdong (CN); Chongqing HKC Optoelectronics Technology Co., Ltd., Chongqing (CN)

(72) Inventor: Yu-Jen CHEN, Chongqing (CN)

(21) Appl. No.: 16/082,891

(22) PCT Filed: May 17, 2017
(86) PCT No.: PCT/CN2017/084675

§ 371 Date: Sep. 6, 2018

(30) Foreign Application Priority Data
May 5, 2017 (CN) 201710312557.2

(51) Int. Cl. G09G 3/36; G11C 19/28

(52) U.S. Cl. CPC G09G 3/3648; G09G 2310/0286; G11C 19/28

(57) ABSTRACT

A shift register circuit, includes: shift registers having a multi-stage, shift registers includes: a first switch, including a control end electrically coupled to a first node, a first end electrically coupled to a frequency signal, and a second end electrically coupled to an output pulse signal; a second switch, including a control end electrically coupled to an input pulse signal, a first end electrically coupled to the input pulse signal, and a second end electrically coupled to the first node; a third switch, including a control end electrically coupled to a second node, a first end electrically coupled to the output pulse signal, and a second end electrically coupled to a low preset potential, a fourth switch, including a control end electrically coupled to the second node, a first end electrically coupled to the first node, a second end electrically coupled to the low preset potential.

### BACKGROUND

### Technical Field

This application relates to a circuit structure in a display, and in particular, to a shift register circuit, a method for generating a waveform thereof, and a display panel applying same.

### Related Art

In recent years, with progress of science and technologies, flat panel liquid crystal displays are gradually popular, and have advantages such as the small weight and thickness. Currently, a drive circuit of a flat panel liquid crystal display is mainly formed by connecting to an IC outside a panel. However, the method neither can reduce costs of the product, nor can reduce the thickness of the panel.

Moreover, usually, there is a gate drive circuit, a source drive circuit, and a pixel array in a liquid crystal display device. The pixel array includes a plurality of pixel circuits. Each pixel circuit is opened and closed according to a scanning signal provided by the gate drive circuit, and displays a data image according to a data signal provided by the source drive circuit. By using the gate drive circuit as an example, the gate drive circuit usually includes a multi-stage shift register, and outputs a scanning signal into the pixel array in a manner of transmitting the scanning signal by a shift register at one stage to a shift register at a next stage, so as to sequentially open the pixel circuits and enable the pixel circuits to receive data signals.

Therefore, in a manufacturing process of a drive circuit, a gate drive circuit, in replacement of a drive chip manufactured by externally connecting to an IC, is directly manufactured on an array substrate. The application referred to as a gate on array (GOA) technology may be directly made around a panel, to reduce manufacturing procedures, reduce product costs, and reduce the thickness of the panel. However, potential pull-down of the existing GOA technology is alternatively controlled by two groups of signals, and the working period is 50%. Under this condition, transistors responsible for pulling down the potential are in a status of a positive voltage for a long time and cannot have adequate rest. Consequently, the reliability of the transistors quickly decreases and a risk of electric leakage occurs, directly causing declines of the display quality or even damages of a display device. Therefore, to overcome the deficiency of the foregoing GOA circuit substrate technology, a gate array shift register that has low manufacturing costs and is easy to process is provided.

### SUMMARY

To resolve the foregoing technical problem, an objective of this application is to provide a shift register circuit, a method for generating a waveform thereof, and a display panel applying same, so as to resolve the problem of electric leakage in a GOA circuit substrate, thereby improving the reliability and service of life of products.

The objective of this application is achieved and the technical problem thereof is resolved by using the following technical solutions. A shift register circuit according to this application comprises a plurality of shift registers having a multi-stage, where each of the shift registers comprises: a first switch, including a control end electrically coupled to a first node, a first end electrically coupled to a frequency signal, and a second end electrically coupled to an output pulse signal; a second switch, including a control end of the second switch electrically coupled to an input pulse signal, a first end of the second switch electrically coupled to the input pulse signal, and a second end of the second switch electrically coupled to the first node; a third switch, including a control end of the third switch electrically coupled to a second node, a first end of the third switch electrically coupled to the output pulse signal, and a second end of the third switch electrically coupled to a low preset potential; a fourth switch, including a control end of the fourth switch electrically coupled to the second node, a first end of the fourth switch electrically coupled to the first node, and a second end of the fourth switch electrically coupled to the low preset potential; and a compensation circuit, comprising: a fifth switch, including a control end of the fifth switch electrically coupled to the output pulse signal, a first end of the fifth switch electrically coupled to the output pulse signal, and a second end of the fifth switch electrically coupled to the low preset potential.

Another objective of this application is a method for generating a waveform of a shift register circuit, applied to a plurality of shift registers having a multi-stage, where each of the shift registers comprises a first switch, a second switch, a third switch, a fourth switch, a compensation circuit, a sub pull-down circuit, and a sub pull-down circuit controller, the first switch is configured to generate an output signal of the shift register, and provide the output signal to a shift register at a next stage, and the method for generating a waveform comprises: conducting the first switch, and pulling up, by using a frequency signal, a potential of an output end of the shift registers; reducing a potential difference between a control end and a first end in the fourth switch by adding a compensation circuit; and pulling down the potential of the output end of the shift registers by using the input pulse signal and by using the second switch and the sub pull-down circuit.

Another objective of this application is a liquid crystal display panel, comprising: a first substrate; a second substrate, disposed opposite to the first substrate; and a liquid crystal layer, disposed between the first substrate and the second substrate, and further comprising a shift register circuit, disposed on the first substrate or the second substrate. Moreover, the liquid crystal display panel further comprises a first polarizer disposed on an outer surface of the first substrate, and a second polarizer disposed on an outer surface of the second substrate, where polarization directions of the first polarizer and the second polarizer are parallel to each other. The first substrate is an active array substrate, and the second substrate is a color filter (CF) substrate.

This application may further resolve the technical problem thereof by using the following technical measures.

In an embodiment of this application, a sub pull-down circuit, electrically coupled to the first node, the output pulse signal, and the low preset potential in the shift registers is further comprised.

In an embodiment of this application, a sub pull-down circuit controller, electrically coupled to the low preset potential of the shift registers and the sub pull-down circuit is further comprised.

In an embodiment of this application, the compensation circuit is configured to reduce a potential difference between the control end and the first end in the fourth switch.

In an embodiment of this application, in the method for generating a waveform, the step of reducing a potential difference between a control end and a first end in the fourth switch by adding a compensation circuit comprises: adding a fifth switch into the shift registers, where a control end of the fifth switch is electrically coupled to an output pulse signal, a first end of the fifth switch is electrically coupled to the output pulse signal, and a second end of the fifth switch is electrically coupled to a low preset potential.

In an embodiment of this application, the method for generating a waveform further comprises a sub pull-down circuit, electrically coupled to the first node, the output pulse signal, and the low preset potential in the shift registers.

In an embodiment of this application, the method for generating a waveform further comprises a sub pull-down circuit controller, electrically coupled to the low preset potential of the shift registers and the sub pull-down circuit.

In an embodiment of this application, in the method for generating a waveform, the compensation circuit is configured to reduce a potential difference between the control end and the first end in the fourth switch.

This application resolves the problem of electric leakage in a GOA circuit substrate, thereby improving the reliability and service of life of products.

### BRIEF DESCRIPTION OF THE DRAWINGS

FIG. 1a is a schematic diagram of an exemplary liquid crystal display;

FIG. 1b is a schematic diagram of a liquid crystal display according to an embodiment of this application;

FIG. 1c is a schematic diagram of a waveform of lifting points in an exemplary gate drive circuit substrate;

FIG. 2a is a schematic diagram of an exemplary shift register circuit;

FIG. 2b is a schematic diagram of a waveform generated due to electric leakage in an exemplary shift register circuit;

FIG. 2c is a schematic diagram of a potential difference generated due to electric leakage in an exemplary shift register circuit;

FIG. 2d is a schematic diagram of a transistor in an exemplary shift register circuit;

FIG. 3a is a schematic diagram of a shift register circuit according to an embodiment of this application;

FIG. 3b is a schematic diagram of a compensation circuit in a shift register circuit according to an embodiment of this application;

FIG. 3c is a schematic diagram of a potential difference generated in a shift register circuit having a compensation circuit according to an embodiment of this application;

FIG. 3d is a schematic diagram of a transistor in a shift register circuit according to an embodiment of this application; and

FIG. 4 is a schematic diagram of a liquid crystal display panel according to another embodiment of this application.

### DETAILED DESCRIPTION

The following embodiments are described with reference to the accompanying drawings, which are used to exemplify specific embodiments for implementation of this application. Terms about directions mentioned in this application, such as “on”, “below”, “front”, “back”, “left”, “right”, “in”, “out”, and “side surface” merely refer to directions of the accompanying drawings. Therefore, the used terms about directions are used to describe and understand this application, and are not intended to limit this application.

The accompanying drawings and the description are considered to be essentially exemplary, rather than limitative. In figures, units with similar structures are represented by using the same reference number. In addition, for understanding and ease of description, the size and the thickness of each component shown in the accompanying drawings are arbitrarily shown, but this application is not limited thereto.

In the accompanying drawings, for clarity, thicknesses of a layer, a film, a panel, an area, and the like are enlarged. In the accompanying drawings, for understanding and ease of description, thicknesses of some layers and areas are enlarged. It should be understood that when a component such as a layer, a film, an area, or a base is described to be “on” “another component”, the component may be directly on the another component, or there may be an intermediate component.

In addition, in this specification, unless otherwise explicitly described to have an opposite meaning, the word “include” is understood as including the component, but not excluding any other component. In addition, in this specification, “on” means that a component is located on or below a target component, but does not mean that the component needs to be located on top of the gravity direction.

To further describe the technical means adopted in this application to achieve the preset invention objective and effects thereof, specific implementations, structures, features, and effects of a shift register circuit, a method for generating a waveform thereof, and a display panel applying same according to this application are described in detail below with reference to the drawings and preferred embodiments.

A liquid crystal panel of this application may include an active array substrate, a CF substrate, and a liquid crystal layer formed between the active array substrate and the CF substrate.

In an embodiment, the liquid crystal panel of this panel may be a curved surface display panel.

In an embodiment, an active array substrate and a CF substrate of the application may be formed on a same substrate.

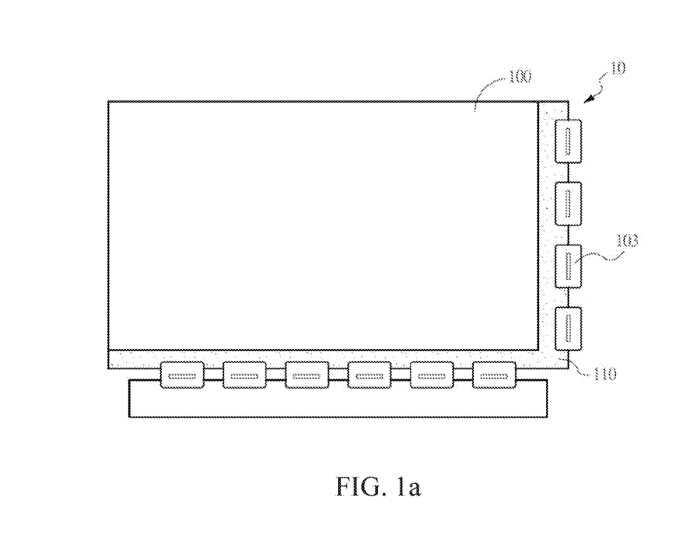

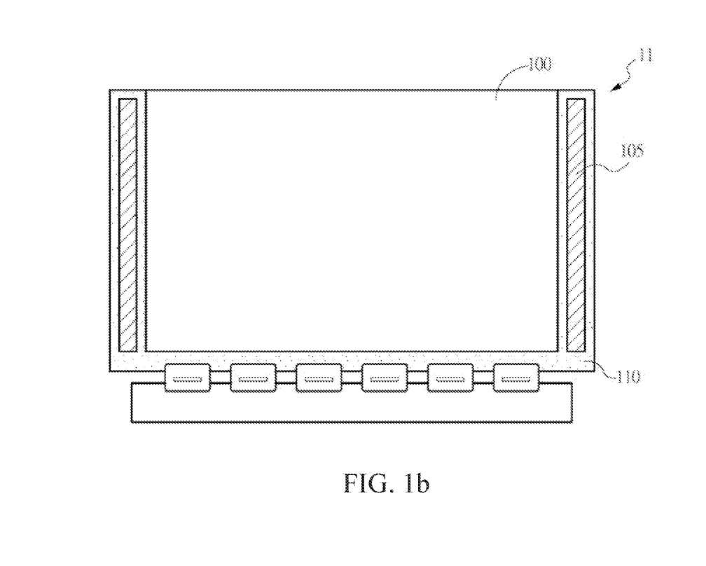

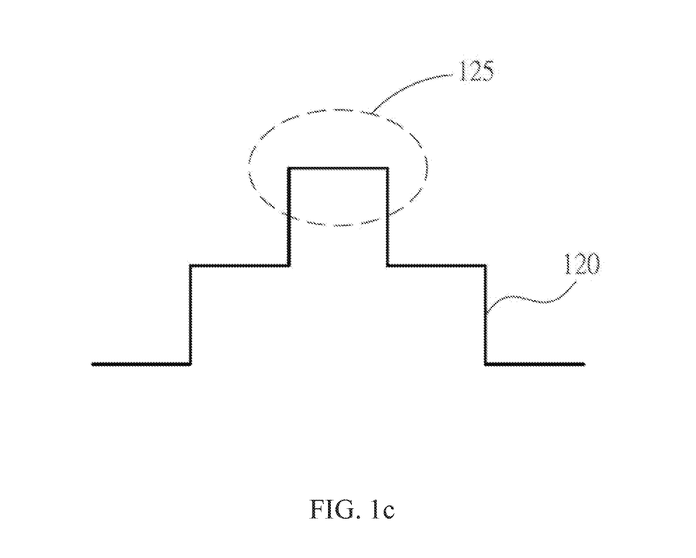

FIG. 1a is a schematic diagram of an exemplary liquid crystal display. Referring to FIG. 1a, a liquid crystal display 10 includes a CF substrate 100, an active array substrate 110, and a driving chip 103 for driving a circuit.

FIG. 1b is a schematic diagram of a liquid crystal display according to an embodiment of this application. Referring to FIG. 1b, in an embodiment of this application, a liquid crystal display 11 having a GOA includes a CF substrate 100, an active array substrate 110, and a GOA 105 configured to manufacture a gate drive circuit on the active array substrate 110.

FIG. 1c is a schematic diagram of a waveform of lifting points in an exemplary gate drive circuit substrate. Referring to FIG. 1c, in a waveform 120 of lifting points in a gate drive circuit substrate, the waveform 120 has a high voltage level 125.

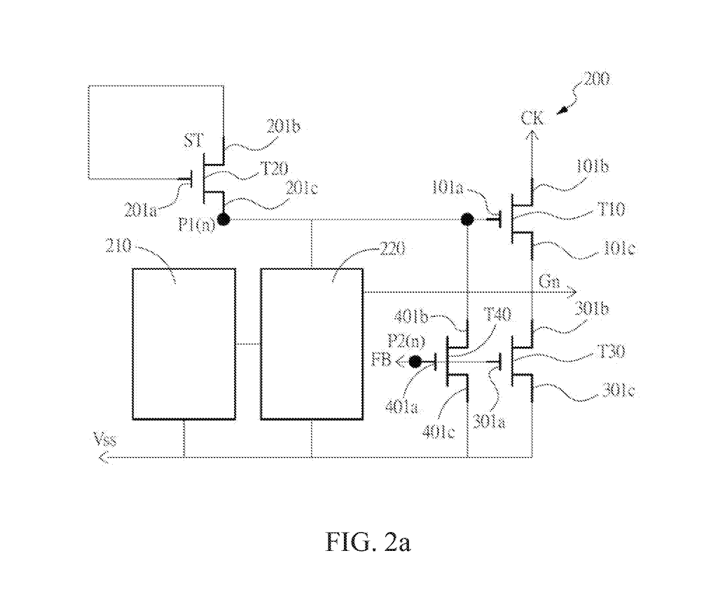

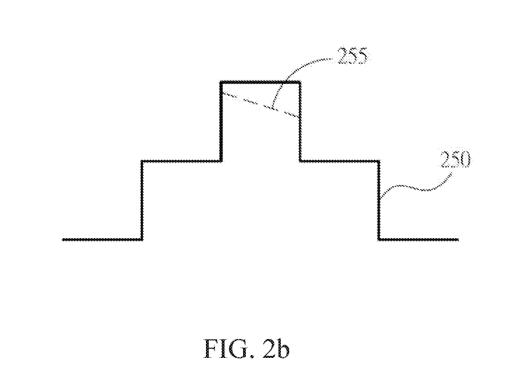

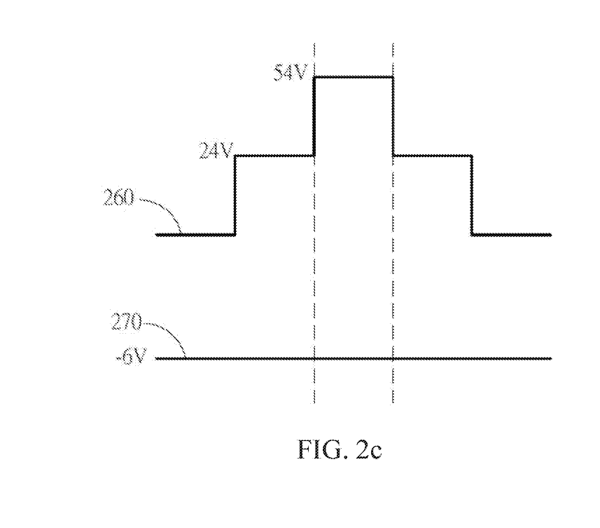

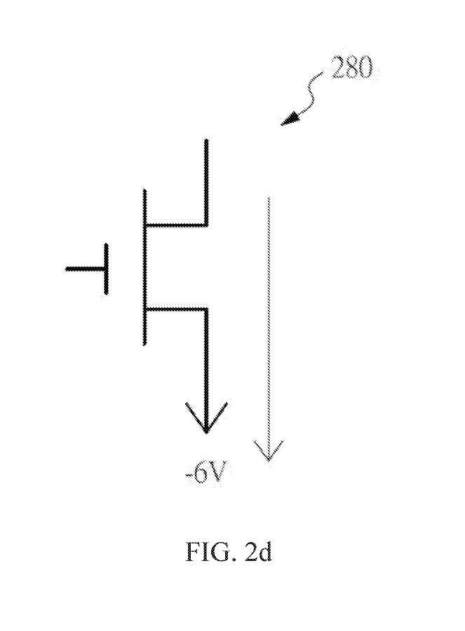

FIG. 2a is a schematic diagram of an exemplary shift register circuit. Referring to FIG. 2a, a shift register circuit includes shift registers having a multi-stage, where each of the shift registers 200 includes: a first switch T10, including a control end 101a of the first switch T10 electrically coupled to a first node P1(n), a first end 101b of the first switch T10 is electrically coupled to a frequency signal CK, and a second end 101c of the first switch T10 electrically coupled to an output pulse signal Gn; a second switch T20, including a control end 201a of the second switch T20 electrically coupled to an input pulse signal ST, a first end 201b of the second switch T20 electrically coupled to the input pulse signal ST, and a second end 201c of the second switch T20 electrically coupled to the first node P1(n); a third switch T30, including a control end 301a of the third switch T30 electrically coupled to a second node P2(n), a first end 301b of the third switch T30 electrically coupled to the output pulse signal Gn, and a second end 301c of the third switch T30 electrically coupled to a low preset potential Vss; a fourth switch T40, including a control end 401a of the fourth switch T40 electrically coupled to the second node P2(n), a first end 401b of the fourth switch T40 electrically coupled to the first node P1(n), and a second end 401c of the fourth switch T40 electrically coupled to the low preset potential Vss.

In an embodiment, a sub pull-down circuit 220, electrically coupled to the first node P1(n), the output pulse signal Gn, and the low preset potential Vss in the shift registers 200 is further included.

In an embodiment, a sub pull-down circuit controller 210, electrically coupled to the low preset potential Vss of the shift registers 200 and the sub pull-down circuit 220 is further included.

FIG. 2b is a schematic diagram of a waveform generated due to electric leakage in an exemplary shift register circuit. FIG. 2c is a schematic diagram of a potential difference generated due to electric leakage in an exemplary shift register circuit. FIG. 2d is a schematic diagram of a transistor in an exemplary shift register circuit. Referring to FIG. 2b, in a waveform 250 generated by lifting points due to electric leakage in a gate drive circuit substrate, the waveform 250 has a chamfered waveform 255.

Referring to FIG. 2a and FIG. 2c, in an embodiment, a potential waveform 270 of the control end 401a and a potential waveform 260 of the first end 401b in the fourth switch T40 are shown in FIG. 2c.

Referring to FIG. 2a and FIG. 2d, in an embodiment, a current flowing direction of a transistor 280 in the fourth switch T40 is shown in FIG. 2d.

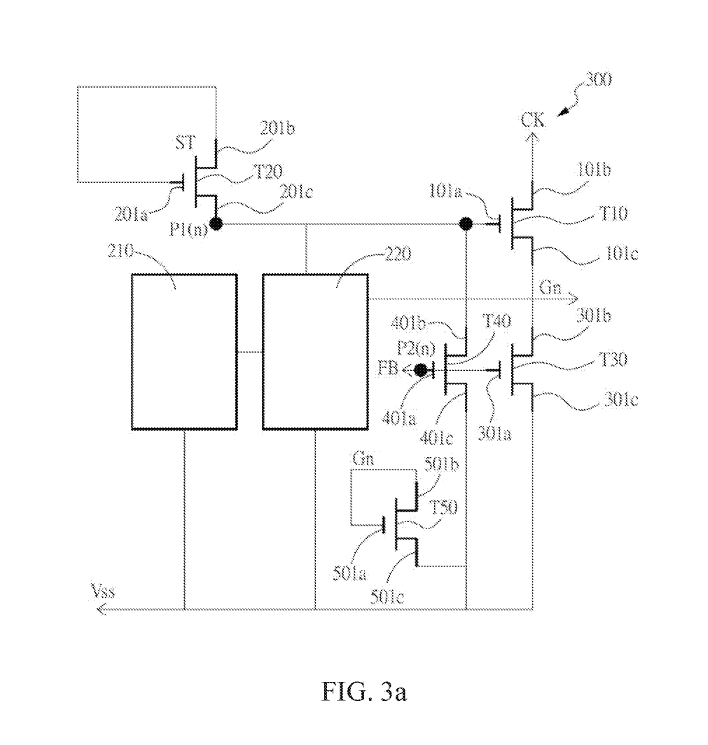

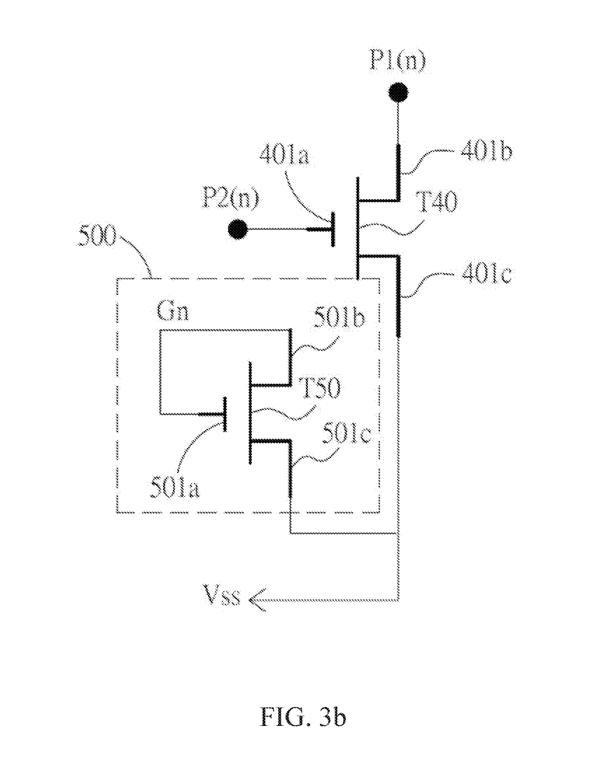

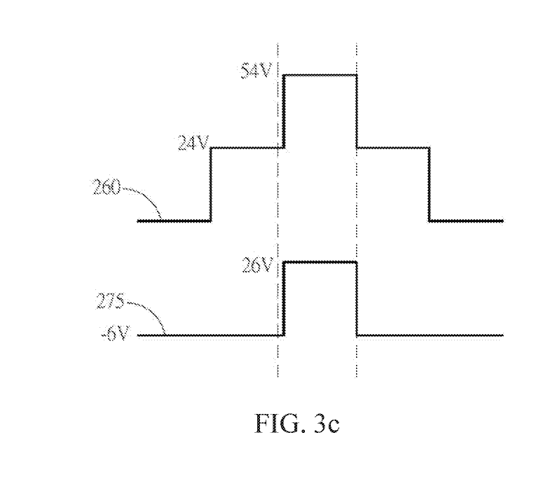

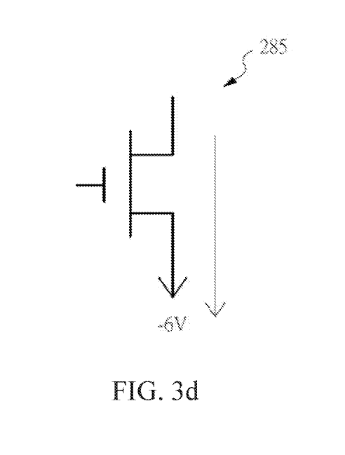

FIG. 3a is a schematic diagram of a shift register circuit according to an embodiment of this application. FIG. 3b is a schematic diagram of a compensation circuit in a shift register circuit according to an embodiment of this application. Referring to FIG. 3a and FIG. 3b, a shift register circuit includes a plurality of shift registers having a multi-stage, where each of the shift registers 300 includes: a first switch T10, including a control end 101a of the first switch T10 electrically coupled to a first node P1(n), a first end 101b of the first switch T10 electrically coupled to a frequency signal CK, and a second end 101c of the first switch T10 electrically coupled to an output pulse signal Gn; a second switch T20, including a control end 201a of the second switch T20 electrically coupled to an input pulse signal ST, a first end 201b of the second switch T20 electrically coupled to the input pulse signal ST, and a second end 201c of the second switch T20 electrically coupled to the first node P1(n); a third switch T30, including a control end 301a of the third switch T30 electrically coupled to a second node P2(n), a first end 301b of the third switch T30 electrically coupled to the output pulse signal Gn, and a second end 301c of the third switch T30 electrically coupled to a low preset potential Vss; a fourth switch T40, including a control end 401a of the fourth switch T40 electrically coupled to the second node P2(n), a first end 401b of the fourth switch T40 electrically coupled to the first node P1(n), and a second end 401c of the fourth switch T40 electrically coupled to the low preset potential Vss; and a compensation circuit 500, including: a fifth switch T50, including a control end 501a of the fifth switch T50 electrically coupled to the output pulse signal Gn, a first end 501b of the fifth switch T50 electrically coupled to the output pulse signal Gn, and a second end 501c of the fifth switch T50 electrically coupled to the low preset potential Vss.

In an embodiment, a sub pull-down circuit 220, electrically coupled to the first node P1(n), the output pulse signal Gn, and the low preset potential Vss in the shift registers 300 is further included.

In an embodiment, a sub pull-down circuit controller 210, electrically coupled to the low preset potential Vss of the shift registers 300 and the sub pull-down circuit 220 is further included.

In an embodiment, the compensation circuit 500 is configured to reduce a potential difference between the control end 401a and the first end 401b in the fourth switch T40 to avoid electric leakage.

Referring to FIG. 3a and FIG. 3b, a method for generating a waveform of a shift register circuit, applied to a plurality of shift registers having a multi-stage is provided, where each of the shift registers 300 includes a first switch T10, a second switch T20, a third switch T30, a fourth switch T40, a compensation circuit 500, a sub pull-down circuit 220, and a sub pull-down circuit controller 210, the first switch T10 is configured to generate an output signal Gn of the shift registers 300, and provide the output signal Gn to a shift register at a next stage, and the method for generating a waveform includes: conducting the first switch T10, and pulling up, by using a frequency signal CK, a potential of an output end of the shift registers 300; reducing a potential difference between a control end 401a and a first end 401b in the fourth switch T40 by adding a compensation circuit 500; and pulling down the potential of the output end of the shift registers 300 by using the input pulse signal ST and by using the second switch T20 and the sub pull-down circuit 220.

In an embodiment, in the method for generating a waveform, the step of reducing a potential difference between a control end 401a and a first end 401b in the fourth switch T40 by adding a compensation circuit 500 includes: adding a fifth switch T50 into the shift registers 300, including a control end 501a of the fifth switch T50 electrically coupled to an output pulse signal Gn, a first end 501b of the fifth switch T50 electrically coupled to the output pulse signal Gn, and a second end 501c of the fifth switch T50 electrically coupled to a low preset potential Vss.

In an embodiment, the method for generating a waveform further includes a sub pull-down circuit 220, electrically coupled to the first node P1(n), the output pulse signal Gn, and the low preset potential Vss in the shift registers 300.

In an embodiment, the method for generating a waveform further includes a sub pull-down circuit controller 210, electrically coupled to the low preset potential Vss of the shift registers 300 and the sub pull-down circuit 220.

In an embodiment, in the method for generating a waveform, the compensation circuit 500 is configured to reduce a potential difference between the control end 401a and the first end 401b in the fourth switch T40 to avoid electric leakage.

FIG. 3c is a schematic diagram of a potential difference generated in a shift register circuit having a compensation circuit according to an embodiment of this application; and FIG. 3d is a schematic diagram of a transistor in a shift register circuit according to an embodiment of this application. Referring to FIG. 3b and FIG. 3c, in an embodiment, a potential waveform 275 of the control end 401a and a potential waveform 260 of the first end 401b in the fourth switch T40 are shown in FIG. 3c.

Referring to FIG. 3b and FIG. 3d, in an embodiment, a current flowing direction of a transistor 285 in the fourth switch T40 is shown in FIG. 3b.

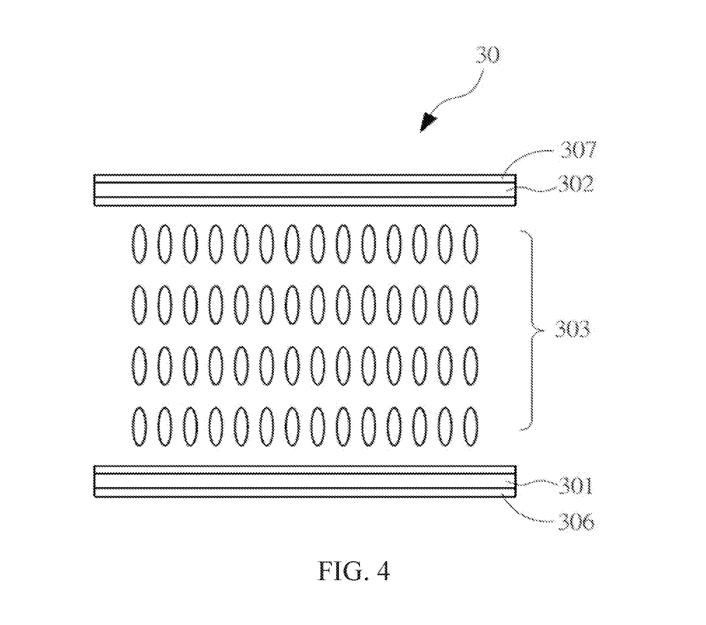

FIG. 4 is a schematic diagram of a liquid crystal display panel according to another embodiment of this application. Referring to FIG. 4 and FIG. 3a, in an embodiment of this application, a liquid crystal display panel 30 includes: a first substrate 301 (such as an active array substrate); a second substrate 302 (such as a CF substrate), disposed opposite to the first substrate 301; and a liquid crystal layer 303, disposed between the first substrate 301 and the second substrate 302, and the liquid crystal display panel 30 further includes a shift register circuit 300 disposed between the first substrate 301 and the second substrate 302 (for example, the shift register circuit 300 is disposed on a surface of the first substrate 301). Moreover, the liquid crystal display panel 30 further includes a first polarizer 306 disposed on an outer surface of the first substrate 301, and a second polarizer 307 disposed on an outer surface of the second substrate 302, where polarization directions of the first polarizer 306 and the second polarizer 307 are parallel to each other.

This application resolves the problem of electric leakage in a GOA circuit substrate, thereby improving the reliability and service of life of products.

Terms such as “in some embodiments” and “in various embodiments” are repeatedly used. Usually, the terms do not refer to the same embodiment; but they may also refer to the same embodiment. Words such as “comprise”, “have”, “include” are synonyms, unless other meanings are indicated in the context.

The foregoing descriptions are merely preferred embodiments of this application, and are not intended to limit this application in any form. Although this application has been disclosed above through the preferred embodiments, the embodiments are not intended to limit this application. Any person skilled in the art can make some equivalent variations or modifications according to the foregoing disclosed technical content without departing from the scope of the technical solutions of this application to obtain equivalent embodiments. Any simple amendment, equivalent change or modification made to the foregoing embodiments according to the technical essence of this application without departing from the content of the technical solutions of this application shall fall within the scope of the technical solutions of this application.

What is claimed is:

1. A shift register circuit, comprising a plurality of shift registers having a multi-stage, wherein each of the shift registers comprises:
a first switch, including a control end electrically coupled to a first node, a first end electrically coupled to a frequency signal, and a second end electrically coupled to an output pulse signal;
a second switch, including a control end of the second switch electrically coupled to an input pulse signal, a first end of the second switch electrically coupled to the input pulse signal, and a second end of the second switch electrically coupled to the first node;
a third switch, including a control end of the third switch electrically coupled to a second node, a first end of the third switch electrically coupled to the output pulse signal, and a second end of the third switch electrically coupled to a low preset potential;
a fourth switch, including a control end of the fourth switch electrically coupled to the second node, a first end of the fourth switch electrically coupled to the first node, and a second end of the fourth switch electrically coupled to the low preset potential; and
a compensation circuit, comprising:
a fifth switch, including a control end of the fifth switch electrically coupled to the output pulse signal, a first end of the fifth switch electrically coupled to the output pulse signal, and a second end of the fifth switch electrically coupled to the low preset potential.

2. The shift register circuit according to claim 1, further comprising a sub pull-down circuit, electrically coupled to the first node, the output pulse signal, and the low preset potential in the shift registers.

3. The shift register circuit according to claim 2, further comprising a sub pull-down circuit controller, electrically coupled to the low preset potential of the shift registers and the sub pull-down circuit.

4. The shift register circuit according to claim 1, wherein the compensation circuit is configured to reduce a potential difference between the control end and the first end in the fourth switch.

5. A method for generating a waveform of a shift register circuit, applied to a plurality of shift registers having a multi-stage, wherein each of the shift registers comprises a first switch, a second switch, a third switch, a fourth switch, a compensation circuit, a sub pull-down circuit, and a sub pull-down circuit controller, the first switch is configured to generate an output signal of the shift register, and provide the output signal to a shift register at a next stage, and the method for generating a waveform comprises:
conducting the first switch, and pulling up, by using a frequency signal, a potential of an output end of the shift registers,
reducing a potential difference between a control end and a first end in the fourth switch by adding a compensation circuit; and
pulling down the potential of the output end of the shift registers by using the input pulse signal and by using the second switch and the sub pull-down circuit.

6. The method for generating a waveform of a shift register circuit according to claim 5, wherein the step of reducing a potential difference between a control end and a first end in the fourth switch by adding a compensation circuit comprises:
adding a fifth switch into the shift registers, wherein a control end of the fifth switch is electrically coupled to an output pulse signal, a first end of the fifth switch is electrically coupled to the output pulse signal, and a second end of the fifth switch is electrically coupled to a low preset potential.

7. The method for generating a waveform of a shift register circuit according to claim 5, further comprising a sub pull-down circuit, electrically coupled to the first node, the output pulse signal, and the low preset potential in the shift registers.

8. The method for generating a waveform of a shift register circuit according to claim 5, further comprising a sub pull-down circuit controller, electrically coupled to the low preset potential of the shift registers and the sub pull-down circuit.

9. The method for generating a waveform of a shift register circuit according to claim 5, wherein the compensation circuit is configured to reduce the potential difference between the control end and the first end in the fourth switch.

10. A liquid crystal display panel, comprising:
a first substrate;
a second substrate, disposed opposite to the first substrate; and
a liquid crystal layer, disposed between the first substrate and the second substrate, wherein
a first polarizer is disposed on an outer surface of the first substrate, a second polarizer is disposed on an outer surface of the second substrate, and polarization directions of the first polarizer and the second polarizer are parallel to each other; and
a shift register circuit, disposed on the first substrate or the second substrate.

11. The liquid crystal display panel according to claim 10, wherein the shift register circuit comprises a plurality of shift registers having a multi-stage, wherein each of the shift registers comprises:
a first switch, including a control end electrically coupled to a first node, a first end electrically coupled to a frequency signal, and a second end electrically coupled to an output pulse signal;
a second switch, including a control end of the second switch electrically coupled to an input pulse signal, a first end of the second switch electrically coupled to the input pulse signal, and a second end of the second switch electrically coupled to the first node;
a third switch, including a control end of the third switch electrically coupled to a second node, a first end of the third switch electrically coupled to the output pulse signal, and a second end of the third switch electrically coupled to a low preset potential;
a fourth switch, including a control end of the fourth switch electrically coupled to the second node, a first end of the fourth switch electrically coupled to the first node, and a second end of the fourth switch electrically coupled to the low preset potential; and
a compensation circuit, comprising: a fifth switch, including a control end of the fifth switch electrically coupled to the output pulse signal, a first end of the fifth switch electrically coupled to the output pulse signal, and a second end of the fifth switch electrically coupled to the low preset potential.

12. The liquid crystal display panel according to claim 11, further comprising a sub pull-down circuit, electrically coupled to the first node, the output pulse signal, and the low preset potential in the shift registers.

13. The liquid crystal display panel according to claim 11, further comprising a sub pull-down circuit controller, electrically coupled to the low preset potential of the shift registers and the sub pull-down circuit.

14. The liquid crystal display panel according to claim 11, wherein the compensation circuit is configured to reduce a potential difference between the control end and the first end in the fourth switch.

15. The liquid crystal display panel according to claim 10, wherein the first substrate is an active array substrate, and the second substrate is a color filter (CF) substrate.
